(19) United States
(12) Patent Application Publication
(10) Pub. No.: US 2006/0140236 A1
(43) Pub. Date: Jun. 29, 2006

(54) Semiconductor laser device and optical pick-up device using the same

(75) Inventor: Toru Takayama, Nara-shi (JP)

Correspondence Address: GREENBLUM & BERNSTEIN, P.L.C., 1950 ROLAND CLARKE PLACE, RESTON, VA, 20191, US

(73) Assignee: Matsushita Electric Industrial Co., Ltd., Osaka (JP)

(21) Appl. No.: 11/315,216

(22) Filed: Dec. 23, 2005

(30) Foreign Application Priority Data
Dec. 27, 2004 (JP) 2004-377681

(51) Int. Cl. H01S 5/00

(52) U.S. Cl. 372/50.1

(57) ABSTRACT

A semiconductor laser device includes, on a substrate: an active layer and two clad layers which sandwich the active layer; and a waveguide diverging region formed in a photonic crystal having a photonic band gap, where the waveguide diverging region diverges, in at least two directions, a waveguide region formed between end faces of an optical path.

### BACKGROUND OF THE INVENTION

(1) Field of the Invention

The present invention relates to a semiconductor laser device and an optical pick-up device which uses the semiconductor laser device.

(2) Description of the Related Art

Today, a semiconductor laser device (hereinafter to be referred to as “semiconductor laser”) is used in various fields. Above all, an AlGaInP semiconductor laser is broadly used as a light source in the field of optical disk system, for it is possible, with such AlGaInP semiconductor laser, to obtain a laser beam with a waveband of 650 nm. One of the representative semiconductor lasers is a semiconductor laser with a double-hetero structure which includes an active layer and two clad layers that sandwich the active layer, and in which one of the clad layers forms a mesa-shaped ridge (see reference to Japanese Laid-Open Application No. 2001-196694).

FIG. 1 shows an example of the AlGaInP semiconductor laser having the structure as described above. Note that a relative portion of the layers described below will be abbreviated. In the semiconductor laser shown in FIG. 1, an n-type GaAs buffer layer 102, a n-type GaInP buffer layer 103, an n-type (AlGa) InP clad layer 104 are sequentially stacked on an n-type GaAs substrate 101 whose main surface is inclined by 15 degrees in a direction [011] from a planar surface (100). A strain quantum well active layer 105, a p-type (AlGa) InP first clad layer 106, a p-type (or non-doped) GaInP etching stop layer 107, a p-type (AlGa) InP second clad layer 108, a p-type GaInP intermediate layer 109 and a p-type GaAs cap layer 110 are further stacked on the n-type (AlGa) InP clad layer 104. On the p-type GaInP etching stop layer 107, the p-type (AlGa) InP second clad layer 108, the p-type GaInP intermediate layer 109 and the p-type GaAs cap layer 110 are formed as a ridge having a forward mesa shape. An n-type GaAs current block layer 111 is formed on the p-type GaInP etching stop layer 107 as well as on the lateral surface of the ridge, while a p-type GaAs contact layer 112 is stacked on the n-type GaAs current block layer 111 as well as on the p-type GaAs cap layer 110 located in the upper part of the ridge. It should be noted that the strain quantum well active layer 105 is made up of (AlGa) InP layer and GaInP layer.

In the semiconductor laser shown in FIG. 1, electric current applied from the p-type GaAs contact layer 112 concentrates on the ridge owing to the n-type GaAs current block layer 111, and the applied current concentrates on the strain quantum well active layer 105 near the bottom of the ridge. In this way, a state of inverted population of carriers that are necessary for laser oscillation is realized in spite of a small amount of the applied current as less as several tens of mA. Here, light is generated by recombination of carriers, however, the light in a direction vertical to the strain quantum well active layer 105 is confined due to both of the n-type (AlGa) InP clad layer 104 and the p-type (AlGa) InP first clad layer 106. Also, the light in a direction horizontal to the strain quantum well active layer 105 is confined in order to absorb the light generated by the n-type GaAs current block layer 111. As a result, laser oscillation is caused in the case where the gain generated by the applied current exceeds a loss in a waveguide within the strain quantum well active layer 105.

When the semiconductor laser tries to gain high-power operation at high heat of 75 degrees or higher, thermal saturation is generated. The thermal saturation is a phenomenon that differential quantum efficiency gradually decreases as a current value increases with regard to the current-light output characteristics. Such thermal saturation is caused by carrier overflow generated as a result of an increase in active-carrier density in the active layer due to an increase of operating current value, by which thermally-excited carriers leaks out onto a potential barrier between the active layer and the clad layer, and even over to the clad layer. The carrier overflow being generated, not only luminous efficiency decreases because of the less amount of carriers that are combined through radiative-recombination in the active layer, but also exothermic heat of elements increases since the energy generated by non-radiative recombination of the carriers that are leaked out to the clad layer is changed into heat. This further increases the overflow of the carriers.

In order to prevent such phenomenon, it is necessary to decrease the active-carrier density in the active layer during the high-power operation, and to reduce the amount of the carriers that leak out from the active layer to the clad layer. To decrease the active-carrier density in the active layer, it is effective to decrease the density of the carriers to be injected per unit area.

For example, in the case of the AlGaInP red semiconductor laser for use as a light source of DVD, with speeding up of rewritable DVD, the method of decreasing the density of the carriers injected per unit area by extending the length of a resonator of the semiconductor laser up to 1300 μm is applied so that the laser operates at the heat of 75 degrees or higher and with an output of 200 mW or higher.

In view of the further speeding up of DVD or multi-layered writing of DVD optical disk system, optical output power of 300 mW or so is required of the red semiconductor laser. It is assumed that 1500 μm or more is required for the length of a resonator in order to achieve such high-power characteristics. Thus, the problem is that such long resonator causes not only a size increase of laser package but also an increase in a per-piece cost of semiconductor laser element.

### SUMMARY OF THE INVENTION

The present invention is conceived in view of the above problem, and an object of the present invention is to provide a semiconductor laser which enables operation at high temperature and with high-power power, despite that the resonator length is short.

The semiconductor laser of the present invention includes, on a substrate, an active layer and two clad layers which sandwich the active layer, the semiconductor laser device comprising a waveguide diverging region which diverges, in at least two directions, a waveguide region that is formed between end faces of an optical path, the waveguide diverging region being formed in a photonic crystal having a photonic band gap.

The semiconductor laser device of the present invention may have a structure in which semiconductor lasers are integrated on a substrate which allow light of at least two types of wavelength to emerge, each laser including an active layer and two clad layers which sandwich the active layer, wherein at least one end face of a waveguide region formed between end faces of an optical path includes a waveguide diverging region which diverges the waveguide region into two directions and is formed in a photonic crystal having a photonic band gap.

The optical pick-up device of the present invention includes the semiconductor laser device as described above, and a light-receiving area which receives a reflected light being a light which emerges from said semiconductor laser device and is reflected on a storage medium.

As is apparent from the above description, the present invention can provide the semiconductor laser device with excellent temperature characteristic and an optical axis of FFP being stabilized, which enables fundamental transverse mode oscillation even in high-power operation.

For further information about technical background to this application, the disclosure of Japanese Patent Application No. 2004-377681 filed on Dec. 27, 2004 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 shows an example of a conventional semiconductor laser device;

FIG. 2 shows an example of a semiconductor laser device of the present invention;

FIGS. 3A and 3B show microscopic patterns of photonic crystal, according to the present invention;

FIG. 4 shows a pattern of photonic crystal in a diverging region;

FIG. 5 is a graph showing a result of deriving wavelength dependency of transmittance of photonic crystal, according to the present invention;

FIG. 6 is a graph showing an example of a ridge in the semiconductor laser device according to the present invention;

FIG. 7 is a graph showing a result of deriving dependency, on a diverging angle, of a length of a mode conversion region in the semiconductor laser device according to the present invention;

FIG. 8 is a graph showing a result of deriving ridge-width dependency of external differential quantum efficiency in the semiconductor laser device according to the present invention;

FIG. 9 is a graph showing a result of deriving single striped region length dependency of optical output power which thermally saturates, in the semiconductor laser device according to the present invention;

FIG. 10 is a graph showing a result of deriving single striped region length dependency of operating current value in the semiconductor laser device according to the present invention;

FIG. 11 is a graph showing an example of current-light output characteristics in the semiconductor laser device according to the present invention;

FIG. 12A, 12B, 12C and 12D respectively show an example of a method for manufacturing the semiconductor laser device according to the present invention;

FIG. 13E, 13F, and 13G respectively show an example of the method of manufacturing the semiconductor laser device according to the present invention;

FIG. 14 shows an example of an optical pick-up device according to the present invention; and

FIG. 15 shows an example of the optical pick-up device according to the present invention.

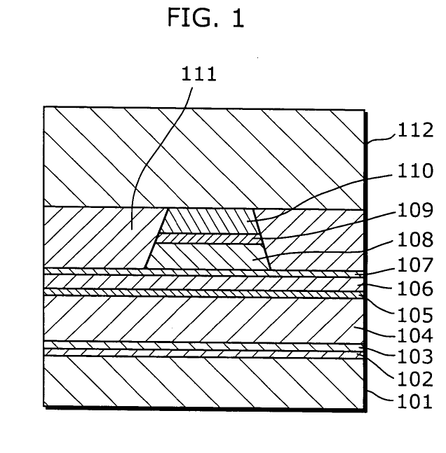

### DESCRIPTION OF THE PREFERRED EMBODIMENT(S)

The following describes the embodiments of the present invention, with reference to the diagrams. It should be noted that the same referential marks are put for the same parts as described in the previous embodiment so as not to repeat the same description.

### First Embodiment

The present embodiment describes the semiconductor laser device (hereinafter to be referred to as “semiconductor laser”) according to the present invention.

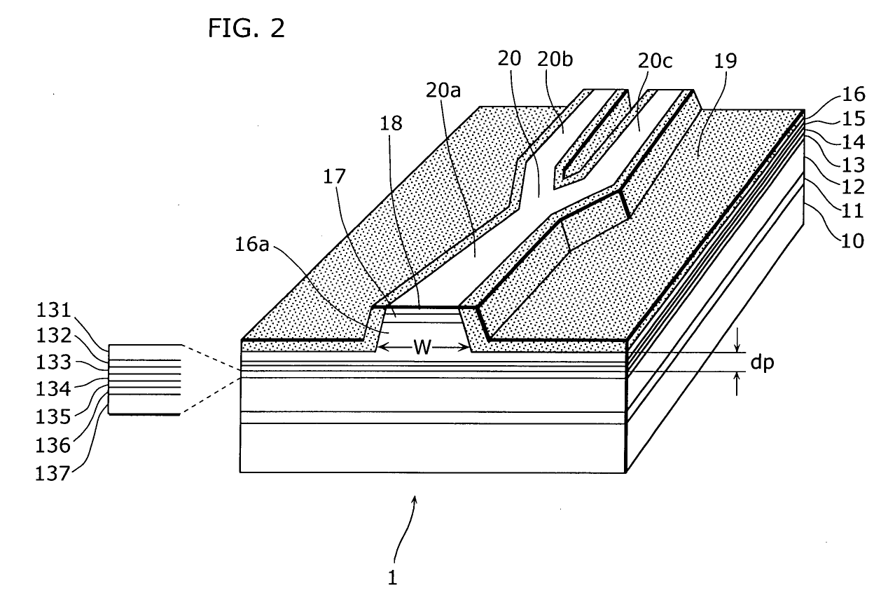

FIG. 2 shows an example of the semiconductor laser device according to the present invention. The semiconductor laser device 1 shown in FIG. 2 is formed on an n-type GaAs substrate 10 which has a main surface inclined by 10 degrees in a direction [011] from a planar surface (100). On the n-type GaAs substrate 10, an n-type GaAs buffer layer 11, an n-type (AlGa) InP first clad layer 12, an active layer 13, a p-type (AlGa) InP second clad layer 14, a p-type GaInP diffraction layer 15, a p-type (AlGa) InP third clad layer 16, a p-type GaInP protection layer 17 and a p-type GaAs contact layer 18 are sequentially stacked. The semiconductor laser device 1 has a double-hetero structure in which the active layer 13 is sandwiched between the two clad layers.

A ridge 16a in a forward mesa-shape is formed on the active layer 13 by the p-type (AlGa) InP second clad layer 14. An n-type AlInP current block layer 19 is further formed so as to cover the lateral surfaces of the ridge 16a.

The ridge 16a having a forward mesa-shape diverges into two directions from the front end face toward the rear end face, from a position where a waveguide diverging region 20 is located in a direction of resonator.

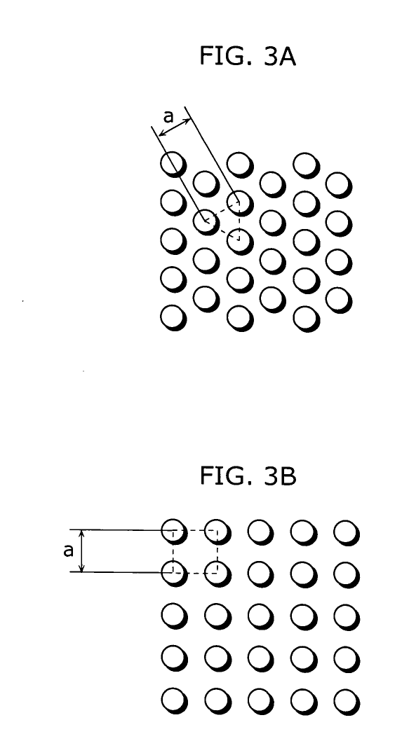

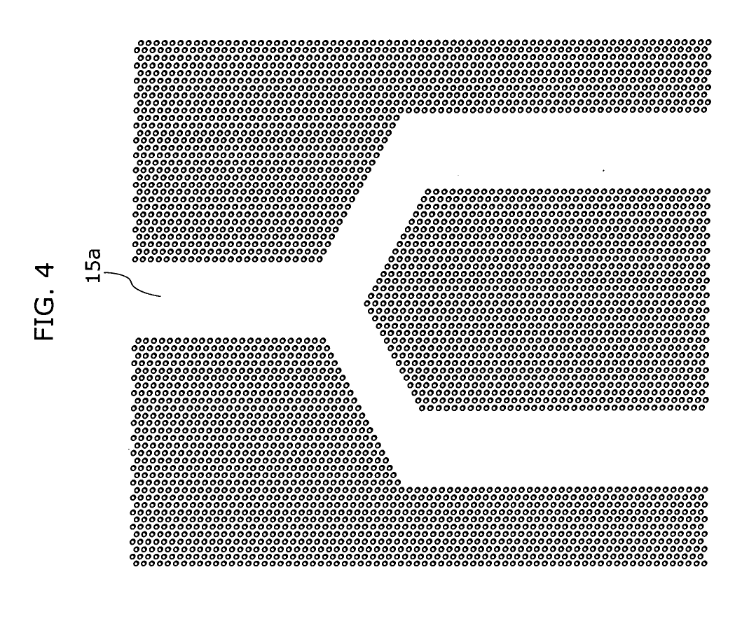

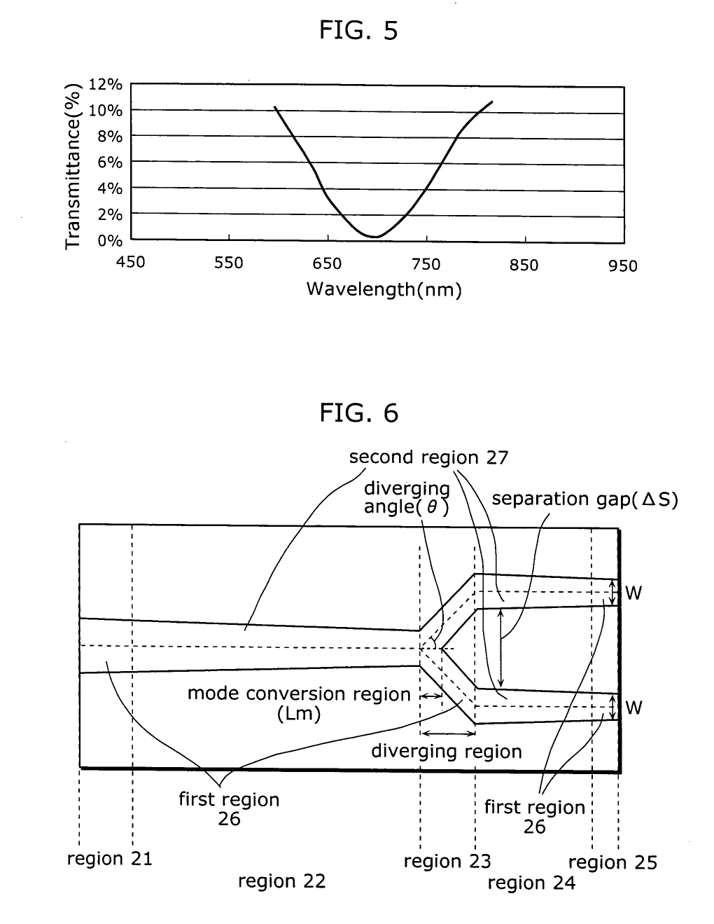

The p-type GaInP diffraction layer 15 located under the waveguide diverging region 20 has a bi-dimensional structure having a periodicity almost equivalent to an integral multiple of half-wavelength of an inter-resonator wavelength of laser emission. Such structure is called photonic crystal. In the photonic crystal, a pillar-like fine structure formed in a triangular lattice array as shown in FIG. 3A or in a tetragonal lattice array as shown in FIG. 3B is regularly arranged so that a length “a” becomes an integral multiple of a half-wavelength of the inter-resonator wavelength, and a photonic band gaps are formed also in different wave number vectors. Once the photonic band gap is formed, light of the wavelength cannot exist in the area where the photonic band is formed within the crystal. Utilizing such nature of photonic crystal, a pillar-like fine structure as shown in FIG. 4 is formed in the p-type GaInP diffraction layer 15 under the waveguide diverging region 20. The fine structure shown in FIG. 4 is formed in a triangular lattice array as shown in FIG. 3A, and the length “a” is 0.19 μm. In the pillar-like fine structure, an area 15a in which the fine structure is not formed is formed along the shape of the waveguide diverging region 20. In the photonic crystal, light cannot exist due to the photonic band gap, but can exist in the area 15a in which the fine structure is not formed. Thus, a guided light can be diverged with less waveguide loss without being dispersed in the waveguide diffraction area 20. In this way, it is possible to form a diverging waveguide with less coupling loss caused by the diversion of the waveguide. The pillar-like area in the fine structure is formed by creating a vacancy in the p-type GaInP diffraction layer 15, and then filling the vacancy with the p-type (AlGa) InP third clad layer 16. FIG. 5 shows a result of deriving wavelength dependency of transmittance in the fine structure. As shown in FIG. 5, transmittance of the light with the wavelength of 660 nm or so is as less as approximately 1%. With such nature of light of the fine structure, the guided light can be guided with less loss, without greatly being dispersed in the waveguide diverging region 20.

The active layer 13 in the example shown in FIG. 2 is a strain quantum well active layer made up of a (AlGa) InP first guide layer 131, a GaInP first well layer 132, (AlGa) InP first barrier layer 133, a GaInP second well layer 134, a (AlGa) InP second barrier layer 135, a GaInP third well layer 136 and a (AlGa) InP second guide layer 137. Note that an example of a relative proportion of each of the layers will be mentioned later.

In the semiconductor laser device 1 shown in FIG. 2, the electric current injected from the p-type GaAs contact layer 20 concentrates on the active layer 13 located near the bottom part of the ridge since the current concentrates only on the ridge due to the n-type AlInP current block layer 19. Therefore, it is possible to realize an inverted population of the carriers necessary for laser oscillation, with the injected electric current as less as dozens of mA. The light which is emitted, due to the recombination of the carriers, in a direction vertical to the main surface of the active layer 13 is to be confined by both of the n-type (AlGa) InP first clad layer 12 and the p-type (AlGa) InP second clad layer 14. The light which is emitted in a direction parallel to the main surface of the active layer 13 is to be confined by the n-type AlInP current block layer 19 whose refractive index is smaller than that of the p-type (AlGa) InP second clad layer 14. Thus, it is possible to provide the semiconductor laser element in which the ridge serves as a waveguide (ridge-waveguide type semiconductor laser element), and which enables fundamental transverse mode oscillation.

The semiconductor laser device 1 shown in FIG. 2 has a diverging region 20 which diverges the single-striped-region 20a into plural directions (two in the embodiment). That is to say that the semiconductor laser device 1 has a single-striped-region 20a and diverging-striped-region 20b and 20c which are formed by diverging the single-striped-region 20a into two directions. Thus, two resonators are provided as laser resonators: one is formed by the single-striped-region 20a and the diverging-striped-region 20b; and the other is formed by the single-striped-region 20a and the diverging-striped-region 20c. The laser beam excited by the two resonators is combined in the single-striped-region 20a. Also, a low-reflectance coating is provided to the front end face of the single-striped-region 20a, while a high-reflectance coating is provided to the rear end face where the ridge is diverged into several directions. Normally, with such coatings, a large optical output power can be effectively obtained from the front end face, and optical density of the front end face of the waveguide becomes higher than that of the rear end face. Here, induced emission within the waveguide is strongly generated in the front end face whose optical density is high, so that the active-carrier density in the active layer becomes relatively lower in the front end face than in the rear end face. In contrast, according to the first embodiment, the rear end face, of the ridge, in which the active-carrier density is high in the normal single ridge stripe structure, is diverged into two directions. It is therefore possible to reduce the active-carrier density in the rear end face, and thereby to reduce the amount of leakage, from the active layer, of the injected carriers which are excited by heat. Thus, the temperature characteristic can be enhanced. Furthermore, differential resistance (hereinafter to be referred to as “Rs”) in current-voltage characteristic of the element can be reduced due to the increase of the area onto which the electric current is injected. Consequently, it is also possible to reduce the amount of exothermic heat, and thereby to enhance the temperature characteristic.

The semiconductor laser device 1 shown in FIG. 2 includes a first region in which a width W of the bottom of the ridge formed by the p-type (AlGa) InP second clad layer 14 is almost constant, and a second region in which the width W gradually varies (see FIG. 6).

With such semiconductor laser device, the first region in which the width of the bottom of the ridge is almost constant stabilizes a relative position for emission with respect to the form of cross-section of the ridge seen from the direction of optical path. Namely, this enables the semiconductor laser device which can stably oscillate even in high-power operation, with a stable optical axis of a far-field pattern (hereinafter to be referred to as “FFP”) of the oscillated laser beam. The second region whose ridge width gradually varies can widen the ridge width so that it is possible to decrease Rs in terms of current-voltage characteristic of the element. Thus, it is possible to provide the semiconductor laser device which makes the optical axis of FFP stable, decreases Rs, and can oscillate in fundamental transverse mode even in high-power operation. Note that the width of the bottom of the ridge is “almost constant” means that the difference between the largest value and the smallest value indicating the width of the bottom of the ridge is 20% of the largest value or smaller.

The concept of the semiconductor laser device according to the present invention is described below.

As already described above, in the semiconductor laser device formed on an inclined substrate, the cross-section of the ridge that is seen from the direction of optical path has a bilaterally asymmetric form, so that kink is easily generated in the state of high-power operation. One of the methods to increase the optical output power generated by the kink is to reduce the asymmetry in the distribution of carrier density. For that, it is necessary to narrow the stripe width and increase the density of the injected current of carriers in the center of the stripe, so as to reduce spatial hole burning of carriers. Thus, it is possible to provide the semiconductor laser device which can stabilize the oscillation even in high-power operation, by reducing the width of the bottom of the ridge. It should be noted that “bilaterally” in the term “bilaterally asymmetric” used in the description means that the cross-section of the semiconductor laser device viewed from the direction of optical path is “bilateral” when the semiconductor laser device is placed so that the substrate becomes the bottom as shown in FIG. 2.

In general, the refraction index of the current block layer is smaller than that of the second clad layer in which the ridge is formed. In the case of using the waveguide laser that applies effective refractive index and that is formed by a block layer which is transparent compared to the oscillated laser beam, it is preferable that the width of the bottom of the ridge is as narrow as possible, in order to obtain stable fundamental transverse mode oscillation by suppressing the lateral mode oscillation of higher level.

Nevertheless, the width of the top surface of the ridge gets narrower as the width of the bottom of the ridge is made narrower. The amount of Rs in the semiconductor laser device is determined based on the width of the top surface of the ridge where the injected current concentrates the most. Therefore, the reduction of the width of the bottom of the ridge in order to obtain the oscillation that is stable even in high-power operation only increases the amount of Rs, and may also increase a level of operating voltage. The increase in the operating voltage causes an increase in active electric power, so that the amount of released heat in the semiconductor laser device becomes greater, which may lead to the degradation of temperature characteristic T₀ or decrease its reliability.

With a high-power laser, reflectance of end face coating film for the front end face which normally extracts laser beam is set to be as low as approximately 5% and reflectance of end face coating film for the rear end face is set to be as high as 90% or higher, so that external differential quantum efficiency in the current-light characteristic can be improved and a high optical output power can be obtained with lower operating current. In this case, the active-carrier density in the rear end face of the active layer is relatively higher than that in the front end face, as described above. Therefore, in the case where the semiconductor laser is operated at high temperature and high-power, leakage current that is the injected carriers which leak from the rear end face of the active layer to the clad layer is easily generated in the rear end face. The increase of the leakage current decreases luminous efficiency of the semiconductor laser and increases an operating-current value, which may lead to the degradation of temperature characteristic T₀ or the decrease of its reliability.

In the case of using such semiconductor laser device for optical disk system, in some cases, the light reflecting back from an optical disk may enter the semiconductor laser. When the components of such reflecting light becomes larger, mode hopping noises are generated, and an S/N ratio at the time of reproducing signals may be degraded. In order to avoid such phenomenon, it is effective to multiply the number of modes of leaser beam that oscillates. The semiconductor laser device, in general, allows the laser beam that oscillates to be multi-mode, by superimposing high frequency current onto driving current. In this case, however, the increase in the amount of Rs decreases the change in operating current with respect to the change in operating voltage, so that the components of the high frequency superimposed current tend to gets smaller as well. As the change in the operating current gets smaller, the change in the wavelength width which has a gain that can oscillate also becomes smaller. This may degrade multi-mode of oscillation spectrum and increase coherent noise from the optical disk. That is to say, the increase in the amount of Rs may lead to the decrease in the reliability of the semiconductor laser device.

With the semiconductor laser device according to the present invention, the ridge is diverged into two directions within a resonator length, and by diverging the rear end face of the ridge, the density of the carriers injected to the rear end face of the active layer is lowered. Thus, it is possible to improve the temperature characteristic of the semiconductor laser.

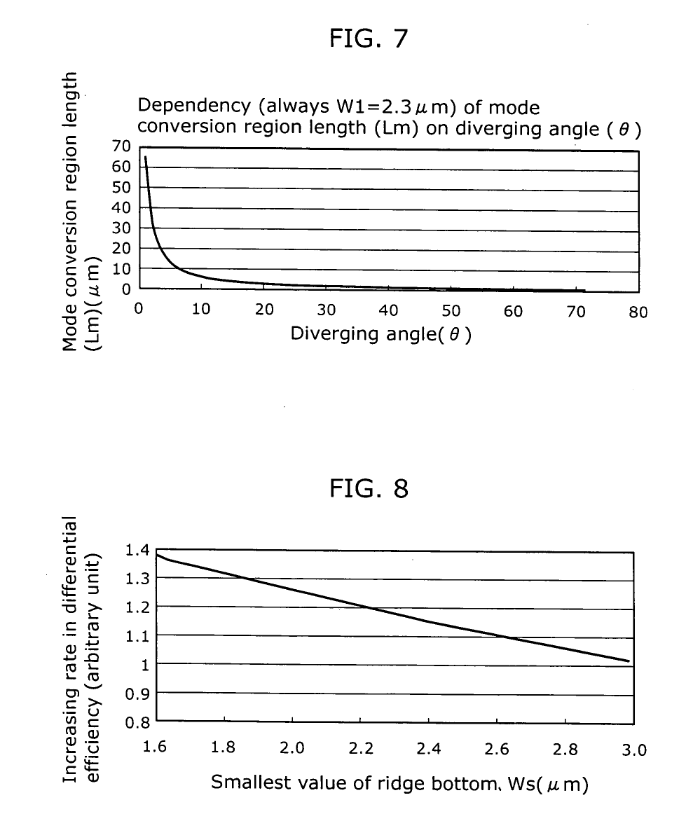

FIG. 6 shows an example of a form of a ridge in the semiconductor laser device according to the present invention. FIG. 6 is a pattern diagram showing a form of the ridge in the case where the semiconductor laser device shown in FIG. 2 is seen from the side of the p-type GaAs contact layer 20. FIG. 7 shows a relationship between a diverging angle (θ) of the ridge in the ridge diverging region shown in FIG. 6 and a mode conversion region length (Lm). In the case where θ is small, Lm gets larger, so that a region whose stripe width is wide gets longer and a region in which high-level lateral mode oscillation is easily generated gets longer. Therefore, θ should not be too small. In the case where θ is large, Lm gets smaller, so that the region whose stripe width is wide gets shorter and the high-level lateral mode oscillation cannot be easily generated.

In the embodiment, the photonic crystal as shown in FIG. 4 is formed near the waveguide diverging region 20 so that it is advantageous that scattering loss in the diverging area does not increase although θ is large. It is therefore possible to diverge the waveguide without causing an increase in an oscillation threshold current value in spite of the divergence of the waveguide. In the embodiment, θ is set to be 60 degrees and the length of Lm is set to be extremely short as 1 μm or shorter. In contrast, a crucial problem is that in the case of diverging the waveguide into two directions in the state where loss is low, without using photonic crystal, scattering loss in the waveguide increases as the angle at which the resonator mode is bent within the diverging region gets large in the case where θ is large. In order to achieve both stability of the waveguide and reduction of waveguide loss, an appropriate value should be provided for the size of θ. In the case of not using photonic crystal, it is desirable that the size of θ is 10 degrees or smaller, in order to reduce the scattering loss due to the bend of the waveguide. The length of Lm should be 20 μm or shorter, while θ shall need 3 degrees or greater in order to reduce as much as possible the region in which high-level lateral mode oscillation is performed. Assuming that the size of θ is 7 degrees based on such observations, it follows that the length of Lm is 10 μm. Within the area defined within 10 μm, the form of light distribution gradually changes so that a propagation constant of the light distribution which propagates the waveguide gradually changes as well. This cannot prevent the generation of the waveguide loss. According to the embodiment, however, a photonic band gap is formed due to the fine structure formed in the p-type GaInP diffraction layer 15 below the waveguide diverging region 20. This allows the light to guide waves perfectly along the waveguide diverging region, so that the guided light can be diverged within a very short distance of 1 μm or shorter, and realize the diverged waveguide with low loss.

The gap (ΔS) between the diverging striped-ridges 20b and 20c depends on the length of the separation region. In the case where ΔS is small, a heat-releasing region in the active layer in the upper part of the diverging striped-ridges 20b and 20c gets closer, which decreases radiation and leads to the degradation of temperature characteristic. In order to thermally separates the heat release in the active layer below the two stripes of the diverging striped-ridges 20b and 20c, it is desirable that ΔS is 15 μm or greater. Therefore, it is defined that the length of the diverging region is 100 μm and ΔS is 23 μm. With this structure, it is possible to reduce the active-carrier density in the active layer in the rear end face where optical density is low, so as to enhance the temperature characteristic.

Next, ridge widths except for a ridge width of the waveguide diverging region 20 will be described. In the embodiment, temperature characteristic and kink level are improved by diverging the ridge into a first region whose width is almost constant and a second region whose width gradually varies, so that the respective widths are controlled.

The length of the first region (i.e. a length in a direction that connects end faces on an optical path) may be determined within the range of 2 to 45% of a resonator length, for example. Above all, the range of 2 to 20% is preferable. The length of the second region (i.e. a length in a direction that connects end faces on an optical path) may be determined within the range of 55 to 98% of the resonator length. The range of 80 to 98% is particularly desirable. Note that in the case where plural second regions are provided, the length of the second region shall be a total length of the respective second regions. The same applies to the case of the first region. It should be noted that the value indicating a resonator length in the semiconductor laser device according to the present invention is not particularly limited. For example, it may be determined within the range of 800 to 1500 μm. In the case of using a semiconductor laser device with an output of 200 mW or greater, the resonator length may be determined within the range of 900 to 1200 μm in order to reduce the amount of leakage current.

With the semiconductor laser device according to the present invention, the width of the bottom of the ridge in the second region becomes narrower from the front end face coated with low reflectance in a direction of resonator toward the rear end face coated with high reflectance. Thus, it is possible to reduce the amount of current injected into the active layer more than the amount injected into the front end face in the rear end face where optical density is low, and to inject more carriers into the active layer of the front end face, where more of the injected carriers are consumed owing to its high optical density, so as to increase external differential quantum efficiency and reduce the amount of leakage current. It is also possible to reduce the active-carrier density in the active layer of the rear end face so as to control a generation of spatial hole burning of carriers. Thus, light distribution is stabilized and generation of kink is reduced, so as to provide the semiconductor laser device that can oscillate in fundamental transverse mode even in high-power operation.

FIG. 8 shows a result of a calculation of dependency of external differential quantum efficiency on ridge width, which is obtained with the semiconductor laser device of the present invention. Here, the width of the bottom of the ridge on the front end face in the second region is fixed to be constantly 3 μm and the resonator length to be 1100 μm. The width of the bottom of the ridge on the rear end face is allowed to vary within the range of 1.6 to 3.0 μm. The level of external differential quantum efficiency in this case is determined based on external differential quantum efficiency of the elements where the width of the bottom of the ridge on the front and rear end faces is determined to be constantly 3.0 μm. As shown in FIG. 8, the external differential quantum efficiency increases as the difference in the width of the bottom of the ridge between front and rear end faces gets larger. The amount of Rs increases if the width of the bottom of the ridge is too narrow, therefore, in the example used in the embodiment, the width of the bottom of the ridge on the front end face is set to be 3.0 μm at maximum while the width on the rear end face is set to be 2.0 μm at minimum.

In the semiconductor laser device of the present invention, the second region may be located between the first region and one end face of an optical path, as well as between the first region and the other end face of the optical path. With this, optical axis of FFP is stabilized and the amount of Rs is reduced, so that it is possible to provide the semiconductor laser device that can oscillate in fundamental transverse mode even in high-power operation.

In the semiconductor laser device of the present invention, the width of the bottom of the ridge in the first region may be almost the same as the width in the second region at the boundary between the first region and the second region. Thus, it is possible to control the change in the distribution of light intensity and to reduce the waveguide loss, at the boundary. Note that “almost the same” here means that the difference in the width of the ridge between the first region and the second region at the boundary is 0.2 μm or smaller.

In the example shown in FIG. 6, the ridge of the semiconductor laser device 1 includes first regions 21, 23 and 25 whose width W1 of the bottom of the ridge is almost constant, and second regions 22 and 24 whose width W2 gradually changes. The lateral surfaces of the ridge at each boundary between the regions are connected. The region 23 is the separation region.

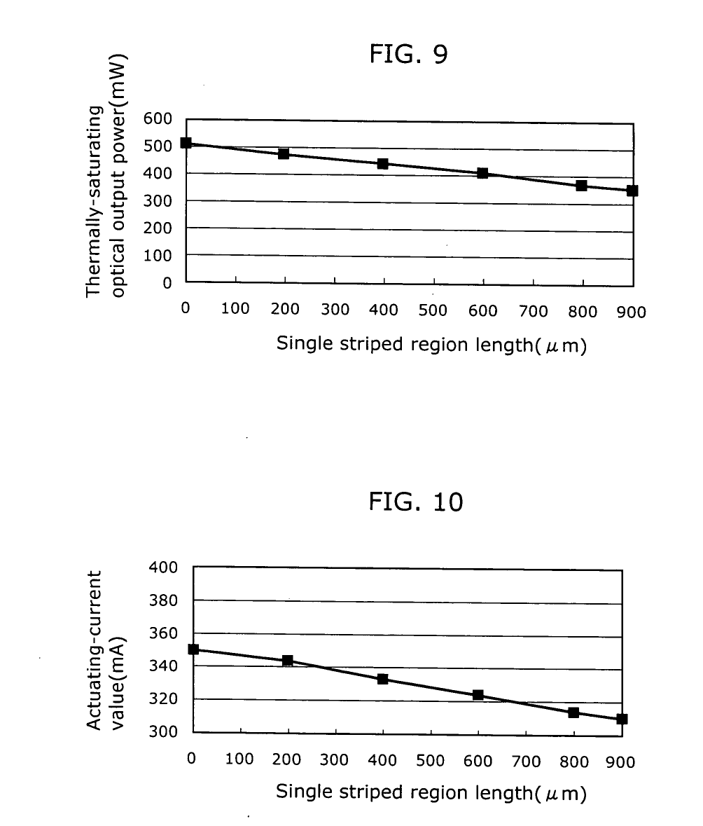

In the embodiment, the length of the regions 21 and 24 is 25 μm and the length of the region 23 is 100 μm, whereas the length of the region 22 is allowed to be variable. FIG. 9 shows the level of heat saturation at the time of driving a pulse with a temperature of 75 degrees, a pulse width of 100 ns and a duty of 50%. FIG. 10 shows a value obtained by measuring an operating-current value at the output of 240 mW. As the length of the region 23 gets longer, a value indicating operating-current as well as an optical output power that thermally saturates increases. This is why it is determined, in the first embodiment, that the optical output power that thermally saturates is 350 mW or greater and the length of the region 23 is 600 μm in order to stably obtain an optical output power of 300 mW or greater.

With such semiconductor laser device, an optical axis of FFP is stabilized, the waveguide loss is further reduced and the amount of Rs is reduced. It is therefore possible to provide the semiconductor laser device that can oscillate in fundamental transverse mode even in high-power operation.

For the semiconductor laser device shown in FIG. 2, thickness, composition, proportional ratio, and conduction type of each layer are not particularly limited to those described in the embodiment. They may be arbitrarily set based on the characteristic(s) required of a semiconductor laser device. For example, each layer may have the thickness, composition and proportional ratio as indicated below. Note that each numerical value shown in parentheses is a thickness of each layer, and the same referential numbers as in FIG. 2 are applied for easy reference.

Some examples of proportional ratio and thickness of each layer are as follows: n-type GaAs buffer layer 11 (0.5 μm); n-type (Al_{0.7}Ga_{0.3)}_{0.51}In_{0.49}P first clad layer 12 (1.2 μm); p-type (A_{0.7}Ga_{0.3})_{0.51}In_{0.49}P second clad layer 14 (0.1 μm); p-type Ga_{0.55}In_{0.45}P diffraction lattice layer 15 (200 nm); p-type (A_{0.7}Ga_{0.3})_{0.51}In_{0.49}P third clad layer 16; p-type Ga_{0.51}In_{0.49}P protection layer 17 (50 nm); and p-type GaAs contact layer 18 (3 μm). An example of the active layer 13 is a strain quantum well active layer made up of the following: (Al_{0.5}Ga_{0.5})_{0.51}In_{0.49}P (50 nm) first guide layer 131; Ga_{0.48}In_{0.52}P (5 nm) first well layer 132; (Al_{0.5}Ga_{0.5})_{0.51}In_{0.49}P (5 nm) first barrier layer 133; Ga_{0.48}In_{0.52}P (5 nm) second well layer 134; (A_{0.5}Ga_{0.5})_{0.51}In_{0.49}P (5 nm) second barrier layer 135; Ga_{0.48}In_{0.52}P (5 nm) third well layer 136; and (Al_{0.5}Ga_{0.5})_{0.51}In_{0.49}P (50 nm) second guide layer 137. An example of p-type (Al_{0.7}Ga_{0.3})_{0.51}In_{0.49}P third clad layer 16 is a second clad layer with the distance between the p-type GaInP protection layer 15 formed in the upper part of the ridge and the active layer 13 is 1.2 μm and the distance dp between the bottom of the ridge and the active layer is 0.2 μm. The thickness of the n-type AlInP current block layer 19 is, for instance, 0.3 μm. Note that, in the example, the width of the top surface of the ridge is narrower than the width of the bottom of the ridge by approximately 1 μm.

The active layer 13 is not particularly limited to the strain quantum well active layer as shown in the example above. For example, a non-strained quantum well active layer or a bulk active layer may be used instead. The conduction type of the active layer 13 is also not limited to the one described in the embodiment, and may be either p-type or n-type. The active layer 13 may be undoped.

As can be seen in the example shown in FIG. 2, with the use of a transparent current block layer for the oscillated laser beam, it is possible to reduce the waveguide loss as well as the value indicating operating-current. In this case, the distribution of the light that propagates through the waveguide can greatly leak to the current block layer so that it is possible to set a difference (Δn) in effective refractive index between the interior and the exterior of the striped region to be 10⁻³. By adjusting the distance dp shown in FIG. 2, Δn can be precisely controlled, which enables the semiconductor laser device that can reduce the value indicating operating-current and oscillate with stability even in high-power operation. It should be noted that the range of Δn may be, for example, 3×10⁻³ to 7×10⁻³. With such range, it is possible to perform oscillation with stability in fundamental transverse mode even in high-power operation.

The value of an oblique angle θ with respect to a specific crystal surface (planar surface (100) in the example shown in FIG. 2) on the substrate is not limited to 10 degrees as shown in FIG. 2. The angle θ may be within the range of 7 to 15 degrees. With such range, the semiconductor laser device may have better temperature characteristic T₀. In the case where the oblique angle θ is smaller than 7 degrees, a band gap in the clad layer becomes smaller due to a formation of natural superlattice, which may decrease the temperature characteristic T₀. In the case where the oblique angle is greater than 15 degrees, an asymmetry in the form of the cross-section of the ridge seen from a direction of optical path may increase and crystallinity of active layer may decrease.

According to the semiconductor layer device of the present invention, the width of the bottom of the ridge in the first region may be within the range of 1.8 to 3.5 μm. With such device, it is possible to reduce the generation of spatial hole burning of carriers in the first region whose width of the bottom of the ridge is constant. Therefore, the semiconductor laser device in which the generation of kink is reduced even in higher output operation.

The width of the bottom of the ridge in the second region may be within the range of 2.0 to 3.5 μm. With such device, it is possible to effectively cut off the high-level lateral mode while better reducing the increase in the amount of Rs in the second region. It is therefore possible to provide the semiconductor laser device that can oscillate in fundamental transverse mode even in high-power operation.

According to the semiconductor laser device of the present invention, a difference between the width of the bottom of the ridge in the first region and the larges value indicating the width of the bottom of the ridge in the second region may be 0.5 μm or smaller. With such semiconductor laser device, it is possible to suppress the increase in the waveguide loss due to the change in the distribution of light intensity, which enables the semiconductor laser device with reduced waveguide loss.

According to the semiconductor laser device of the present invention, the active layer near the end faces may be disordered due to diffusion of impurities. With such device, it is possible to increase a band gap in the active layer near the end faces so as to obtain a more transparent end face window structure for leaser beam. Therefore, the semiconductor laser device does not easily cause catastrophic optical damage (i.e. C.O.D) even with a higher optical output power.

As for the impurities, Si, Zn, Mg and O may be used. The diffusion amount (dope amount) of impurities may be, for instance, within the range of 1×10¹⁷ cm⁻³ to 1×10²⁰ cm⁻³. As for the range of the diffusion, it may be within the range of 10 to 50 μm from the end face of the semiconductor laser element.

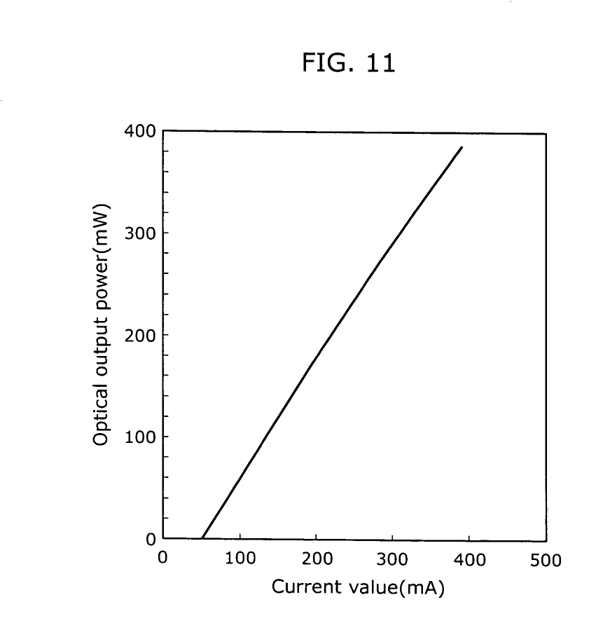

FIG. 11 shows current optical output power characteristic with the same room temperature and CW state as those used for the semiconductor laser device shown in the first embodiment. As shown in FIG. 11, kink is not generated and a stable oscillation in fundamental transverse mode is maintained, even when an optical output power is 300 mW.

It should be noted that the example in FIG. 11 shows that Zn is diffused, with the dope amount of 1×10¹⁹ cm⁻³, onto the active layer near end faces, and the region near the end faces of the active layer has a window structure that is disordered by impurities. Owing to this structure, C.O.D. being a phenomenon in which the end faces are deconstructed by optical output power does not occur even when the output is 300 mW or greater.

### Second Embodiment

In the embodiment, a method for manufacturing the semiconductor laser device described in the first embodiment will be described.

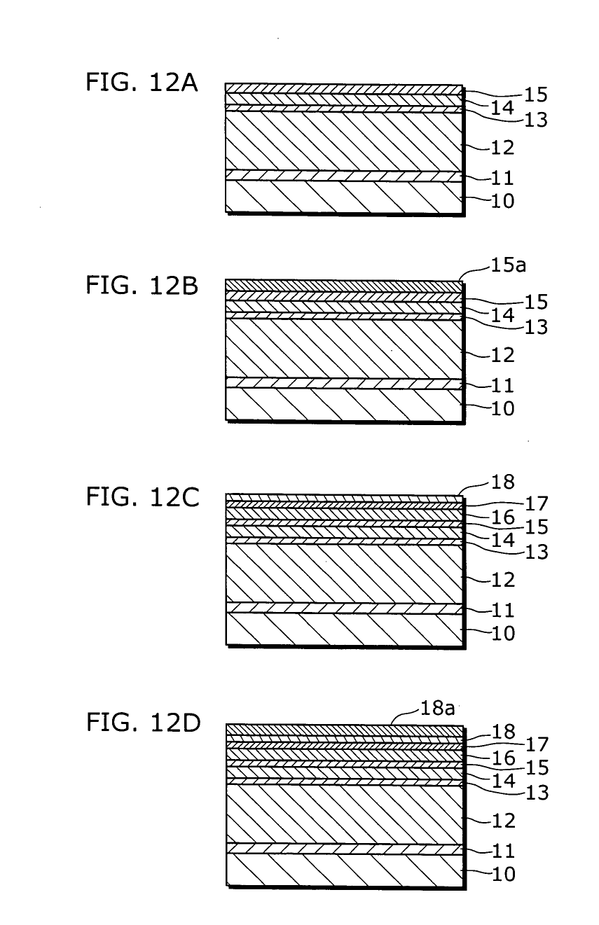

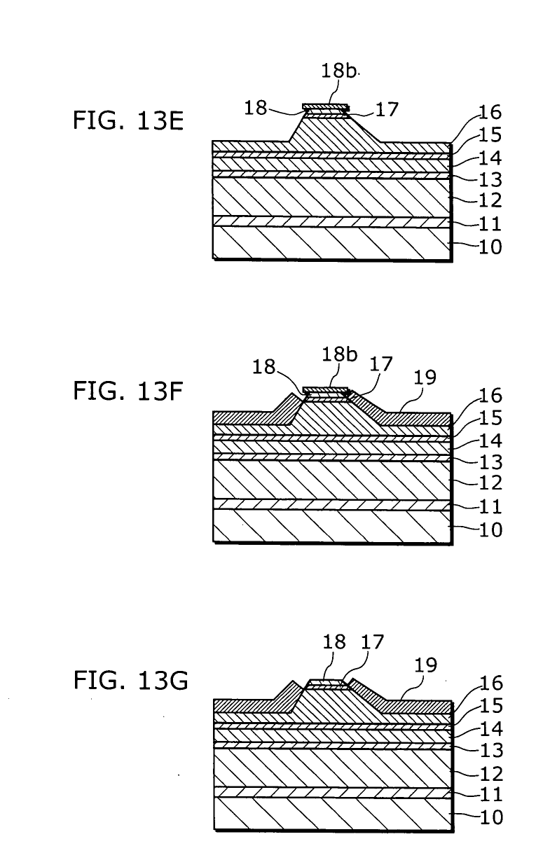

FIGS. 12 and 13 are cross-sectional process diagrams showing an example of the method for manufacturing the semiconductor laser device of the present invention.

First, the n-type GaAs buffer layer 11 (0.5 μm), the n-type (AlGa)InP first clad layer 12 (1.2 μm), the active layer 13, the p-type (AlGa) InP second clad layer 14 (0.1 μm), and the p-type GaInP diffraction layer 15 (200 nm) are formed on the n-type GaAs substrate 10 whose main surface is inclined by 10 degrees in a direction [011] from a planar surface (100) (FIG. 12A). The number indicated in parentheses indicates a thickness of each layer. As for a proportional ratio of each layer the description is omitted. The active layer 13 may be the same as the strain quantum well active layer described in the first embodiment. Note that the proportional ratio of the layers may be the same as in the example shown in the first embodiment. The proportional ratio of each layer may be the same as shown in the example described in the first embodiment. Methods such as MOCVD and MBE may be used, for example, for the formation of each layer.

Next, a resist film 15a is applied onto the p-type GaInP diffraction layer 15 (200 nm) which is a top layer of a stack layer made up of the respective layers as described above (FIG. 12B). The microscopic pattern having an array of triangular lattice, as shown in FIG. 3A, is formed by electronic beam exposure on the resist film 15a. After that, etching is performed to the p-type GaInP diffraction layer 15 either by wet or dry etching, using, as a mask, a resist on which patterning is performed, so as to form such microscopic pattern.

Then, the p-type (AlGa) InP third clad layer 16 (1.08 μm), the p-type GaInP protection layer 17 (500 nm) and the p-type GaAs contact layer 18 (3 μm) are formed on the p-type GaInP diffraction layer 15 (FIG. 12C).

An oxidized silicon film 18a is built up on the p-type GaAs contact layer 18 being the top layer of the stack layer made up of the respective layers (FIG. 12D). The building up may be performed using heat CVD method (atmospheric pressure is 370 degrees), for instance. The thickness may be 0.3 μm, for example.

Then, the region near the end face of the oxidized silicon film 18a (e.g., a region with a width of 50 μm from the end face) is removed so that the p-type GaAs contact layer 18 is exposed. An impurity atom such as Zn is then thermally diffused onto the exposed part, and the region near the end face of the active layer 13 is disordered.

The oxidized silicon film 18a is patterned into a predetermined form. The patterning may be performed using, for example, a combination of a photolithography method and a dry etching method. The predetermined form may be as same as the form of the ridge of the semiconductor laser device according to the present invention. For example, the oxidized silicon film 18a may be patterned into the form of the ridge as shown in FIG. 6. The p-type GaInP protection layer 17, the p-type GaAs contact layer 18 are selectively etched with the use of a hydrochloric acid etchant, while the p-type AlGaInP third clad layer 16 is selectively etched with the use of a sulfuric acid or a hydrochloric acid etchant, using, as a mask, the oxidized silicon film 18b patterned into the predetermined form so as to form a mesa-shaped ridge (FIG. 13E).

An n-type AlInP current block layer 19 is caused to selectively grow on the p-type AlGaInP third clad layer 16, using the oxidized silicon film 18b as a mask (FIG. 13F). The thickness of the n-type AlInP current block layer 19 may be 0.3 μm, for instance. The MOCVD method, for instance, may be used for the growth.

The oxidized silicon film 18b is removed using a hydrofluoric acid etchant (FIG. 13G).

The semiconductor laser device of the present invention can be thus manufactured.

### Third Embodiment

In the embodiment, an optical pick-up device of the present invention will be described.

The optical pick-up device of the present invention includes the semiconductor laser device of the present invention as described above, and a light-receiving area for receiving reflected light being light that outgoes from the semiconductor laser device and that is reflected onto a storage medium.

With such optical pick-up device, an optical axis of FFP is stabilized and the device can operate by oscillation in fundamental transverse mode even in high-power operation.

The optical pick-up device of the present invention may further include a light diverging unit operable to diverge the reflected light, and the light-receiving area may receive the reflected light diverged by the light diverging unit.

The semiconductor laser device and the light-receiving area may be formed on the substrate, according to the present invention. With such formation, a small optical pick-up device can be realized.

The optical pick-up device may further include, on the substrate, an optical element which reflects the light that outgoes from the semiconductor laser device in a normal direction on the surface of the substrate.

The optical element is not limited to the one described above. A reflecting mirror may be used instead.

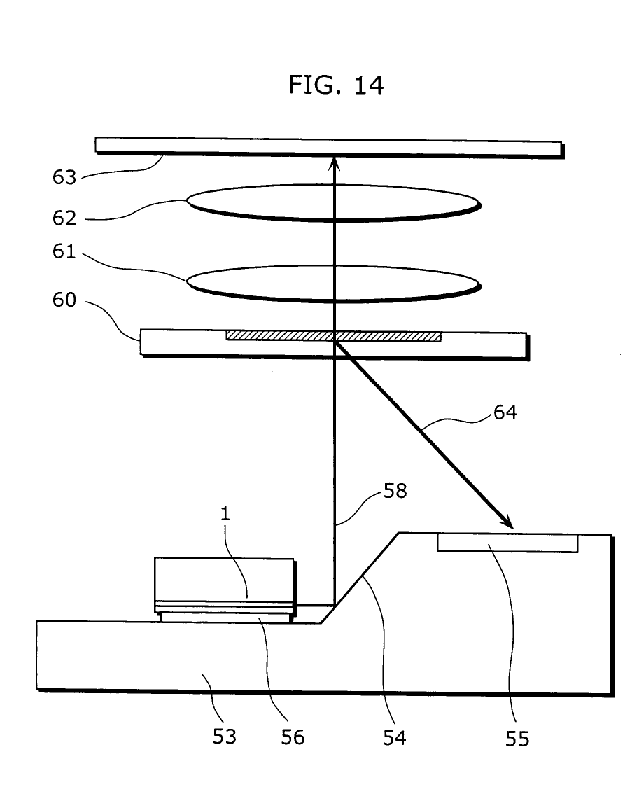

FIG. 14 shows an example of the optical pick-up device of the present invention. In the optical pick-up device shown in FIG. 14, a semiconductor laser device 1 and a light-receiving element 55 serving as a light-receiving area are formed on a substrate 53. The optical pick-up device also includes an optical element 54 which reflects a laser beam 58 that outgoes from the semiconductor laser device 1 in a normal direction on the surface of the substrate 53. The semiconductor laser device 1 is placed on a seat 56 in order to reduce the influence caused by the reflection of the laser beam 58 on the surface of the substrate 53. Note that the optical element 54 is an element formed by processing the surface of the substrate 53 so that a plane direction of crystal emerges by wet etching. A photodiode, for example, may be used as the light-receiving area.

The laser beam 58 that outgoes from the laser is cast in a normal direction by the optical element 54, a diffracted light is generated by a diffraction lattice 60, and the diffracted light is collected onto an optical disk 63 through lenses 61 and 62. Such diffracted light is reflected by the optical disk 63, diffracted again by the diffraction lattice 60, and is made to enter into the light-receiving area. Here, with the formation of plural light-receiving areas according to a pattern of diffraction lattice, it is possible to detect the degree of light-gathering with respect to tracks on the optical disk (focus error signal), and whether or not the light is properly collected on the tracks (tracking error signal), by operating input signals in the plural light-receiving areas.

In the optical pick-up device shown in FIG. 14, the light-receiving area and the semiconductor laser device 1 that is a light emission unit are integrated on the substrate so that a small optical pick-up device can be realized. Since an optical axis of FFP is stabilized and the semiconductor laser device 1 can oscillate in fundamental transverse mode even in high-power operation, it is possible to provide the optical pick-up device adapted to an optical disk of various formats, such as a DVD.

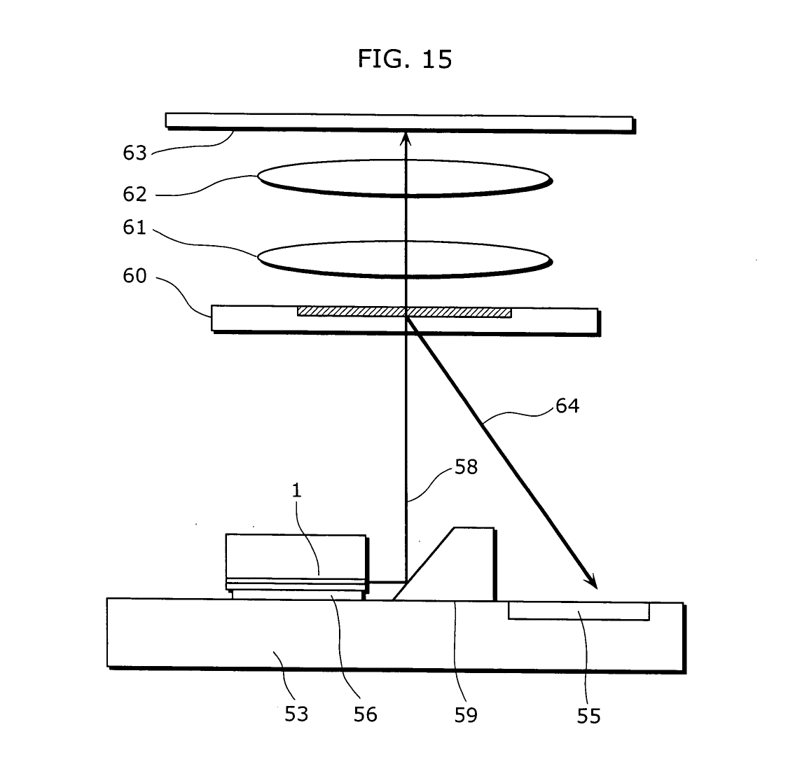

FIG. 15 shows an example of another optical pick-up device of the present invention. As can be seen from the optical pick-up device shown in the diagram, the semiconductor laser device 1 and the light-receiving element 55 are formed on the substrate 53. The optical pick-up device also includes a reflecting mirror 59 which reflects the laser beam 58 that outgoes from the semiconductor laser device 1 in a normal direction on the surface of the substrate 53. Note that the semiconductor laser device 1 is placed on the seat 56 in order to reduce the influence caused by the reflection of the laser beam 58 on the surface of the substrate 53.

With such optical pick-up device as described above, the same effect can be obtained as can be obtained with the optical pick-up device shown in FIG. 14.

Note that the specification describes a GaAlInP semiconductor laser device as a representative example of the semiconductor laser device formed on an inclined substrate and a method of manufacturing the semiconductor laser device as well as the optical pick-up device of the present invention. The present invention, however, is not limited to the semiconductor laser device as described above, and can be applied to the semiconductor laser device formed on a just substrate without an off orientation angle, or with different composition and structure.

In the description, an AlInP layer is used for the current block layer 19, however, an oxidized film material, such as SiO₂, SiN, amorphous silicon and Al₂O₃, which has a smaller band gap and a lower refractive index compared to the clad layer 16 may be used instead. With such structure, it is possible to selectively inject electric current only in the lower part of the ridge by insulating properties of oxidized film, and furthermore, to confine the light distribution in a lateral direction. Thus, stable oscillation in fundamental transverse mode can be performed.

A semiconductor laser, which can cause the light of at least two types of wavelength to outgo, may be integrated on the substrate 10. In such case, if at least one waveguide diverging region 20 as described above is formed on the semiconductor laser, the effect expected with the present invention can be obtained.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The semiconductor laser device of the present invention is advantageous for its excellent temperature characteristic, stable optical axis of FFP and its ability to oscillate in fundamental transverse mode even in high-power operation, and therefore, is useful as an optical pick-up device or the like.

What is claimed is:

1. A semiconductor laser device including, on a substrate, an active layer and two clad layers which sandwich the active layer, said semiconductor laser device comprising
a waveguide diverging region which diverges, in at least two directions, a waveguide region that is formed between end faces of an optical path, said waveguide diverging region being formed in a photonic crystal having a photonic band gap.

2. The semiconductor laser device according to claim 1,
wherein a mesa-shaped ridge is formed at least in one place on said waveguide region.

3. The semiconductor laser device according to claim 2,
wherein an oxidized film is laid on the inclined surface of said mesa-shaped ridge.

4. The semiconductor laser device according to claim 3,
wherein said oxidized film includes at least one layer made up of any one of SiO₂, SiN, amorphous silicon and Al₂O₃.

5. The semiconductor laser device according to claim 2,
wherein a width of a bottom part of said ridge gradually changes.

6. The semiconductor laser device according to claim 2,
wherein a width of a bottom part of said ridge is constant near the end faces.

7. The semiconductor laser device according to claim 1,
wherein a low-reflectance coating is applied on a front end face whereas a high-reflectance coating is applied on a rear end face.

8. The semiconductor laser device according to claim 1,
wherein the active layer is formed by a quantum well active layer, and the active layer near the end faces is disordered due to diffusion of impurities.

9. The semiconductor laser device according to claim 1,
wherein the substrate is an inclined substrate.

10. Semiconductor laser device comprising
semiconductor lasers integrated on a substrate which allow light of at least two types of wavelength to emerge, each laser including an active layer and two clad layers which sandwich the active layer,
wherein at least one end face of a waveguide region formed between end faces of an optical path includes a waveguide diverging region which diverges said waveguide region into two directions and is formed in a photonic crystal having a photonic band gap.

11. An optical pick-up device comprising:
a semiconductor laser which includes, on a substrate: (a) an active layer and two clad layers which sandwich said active layer; and (b) a waveguide diverging region which diverges, in at least two directions, a waveguide region formed between end faces of an optical path, said waveguide diverging region being formed in a photonic crystal having a photonic band gap; and
a light-receiving area which receives a reflected light being a light which emerges from said semiconductor laser device and is reflected on a storage medium.

12. The optical pick-up device according to claim 11, further comprising
a light diverging region which diverges the reflected light,
wherein said light-receiving area receives the reflected light diverged by said light diverging region.

13. The optical pick-up device according to claim 11,
wherein said semiconductor laser device and said light-receiving area are formed on the substrate.

14. The optical pick-up device according to claim 13, further comprising
an optical element, on the substrate, which reflects the light that emerges from said semiconductor laser device in a normal direction of the surface of the substrate.

15. The optical pick-up device according to claim 14,
wherein said optical element is a reflecting mirror.

16. A method of manufacturing a semiconductor laser device which includes, on a substrate, an active layer and two clad layers that sandwich the active layer, said method comprising:
forming a waveguide diverging region in a photonic crystal having a photonic band gap, said waveguide diverging region diverging, in at least two directions, a waveguide region formed between end faces of an optical path.
